(19) United States
(12) Patent Application Publication
(10) Pub. No.: US 2013/0043485 A1
(43) Pub. Date: Feb. 21, 2013

(54) GaN-BASED SEMICONDUCTOR DEVICE

(71) Applicant: Katsunori UENO, Yokohama-shi (JP)

(72) Inventor: Katsunori UENO, Yokohama-shi (JP)

(73) Assignee: ADVANCED POWER DEVICE RESEARCH ASSOCIATION, Yokohama-shi (JP)

(21) Appl. No.: 13/586,008

(22) Filed: Aug. 15, 2012

(30) Foreign Application Priority Data
Aug. 16, 2011 (JP) 2011-177825

(51) Int. Cl. H01L 29/205

(52) U.S. Cl. 257/76; 257/E29.091

(57) ABSTRACT

A p-type GaN-based semiconductor device is provided. Porivded is a GaN-based semiconductor device including: a first channel layer which is formed from a GaN-based semiconductor, and in which a carrier gas of a first conductivity type occurs; a barrier layer formed on the first channel layer from a GaN-based semiconductor having a higher bandgap than the first channel layer; and a second channel layer which is formed on the barrier layer from a GaN-based semiconductor having a lower bandgap than the barrier layer, and in which a carrier gas of a second conductivity type occurs, wherein the carrier concentration of the carrier gas of the second conductivity type is lower in a region below a first gate electrode than in other regions between a first source electrode and a first drain electrode, and is controlled by the first gate electrode.

The contents of the following patent applications are incorporated herein by reference:

No. JP2011-177825 filed on Aug. 16, 2011

### BACKGROUND

1. Technical Field

The present invention relates to a GaN-based semiconductor device.

2. Related Art

Known among GaN-based semiconductor devices are n-type MOS transistors using a 2DEG (2-dimensional electron gas) as a carrier (see, for example, Patent Document 1).

Patent Document 1 Japanese Patent Application Publication No. 2010-109322

Because it is difficult to form a p-type semiconductor layer from a GaN-based semiconductor, it has been difficult to manufacture a p-type transistor using a GaN-based semiconductor. P-type transistors can be used for, for example, complementary transistor structures. Therefore, there has been a demand for p-type transistors using a GaN-based semiconductor.

### SUMMARY

A first aspect of the innovations may provide a GaN-based semiconductor device, including: a first channel layer which is composed of a GaN-based semiconductor, and in which a carrier gas of a first conductivity type occurs; a barrier layer formed on the first channel layer from a GaN-based semiconductor having a higher bandgap than the GaN-based semiconductor of the first channel layer; a second channel layer which is formed on the barrier layer from a GaN-based semiconductor having a lower bandgap than the GaN-based semiconductor of the barrier layer, and in which a carrier gas of a second conductivity type occurs; a first source electrode having an ohmic contact with the second channel layer; a first drain electrode having an ohmic contact with the second channel layer; a first gate electrode formed between the first source electrode and the first drain electrode, wherein a carrier concentration of the carrier gas of the second conductivity type is lower in a region below the first gate electrode than in other regions that are between the first source electrode and the first drain electrode, the carrier concentration being controlled by the first gate electrode.

The summary clause does not necessarily describe all necessary features of the embodiments of the present invention. The present invention may also be a sub-combination of the features described above.

### BRIEF DESCRIPTION OF THE DRAWINGS

FIG. 1 is an exemplary cross-sectional diagram of a MOS type transistor according to a first embodiment of the present invention.

FIG. 2 is a graph showing carrier concentration in the MOS type transistor according to the first embodiment.

FIG. 3 is an exemplary cross-sectional diagram of a MOS type transistor according to a second embodiment of the present invention.

FIG. 4 is an exemplary cross-sectional diagram of a Schottky gate type transistor according to a third embodiment of the present invention.

FIG. 5 is an exemplary cross-sectional diagram of a Schottky gate type transistor according to a fourth embodiment of the present invention.

FIG. 6 is an exemplary cross-sectional diagram of a complementary transistor according to a fifth embodiment of the present invention.

FIG. 7 is an exemplary cross-sectional diagram of a semiconductor device according to a sixth embodiment of the present invention.

FIG. 8 is an exemplary plan diagram of the semiconductor device according to the sixth embodiment.

FIG. 9 is a plan diagram of an inverter according to a seventh embodiment of the present invention.

### DESCRIPTION OF EXEMPLARY EMBODIMENTS

Though some embodiments of the present invention will be described hereinafter, the embodiments do not limit the invention according to the claims. All the combinations of the features described in the embodiments are not necessarily essential to means provided by aspects of the invention.

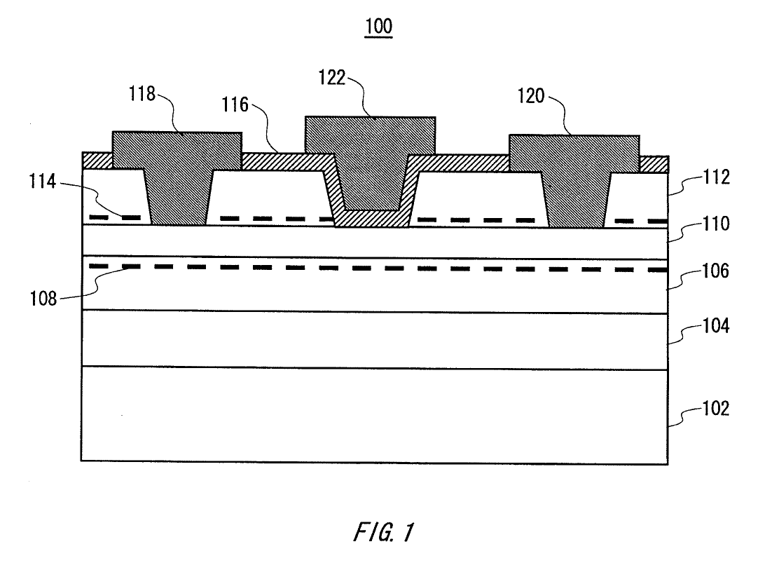

FIG. 1 an exemplary cross-sectional diagram of a MOS type transistor 100 according to a first embodiment of the present invention. The MOS type transistor 100 includes a substrate 102, a buffer layer 104, a first channel layer 106, a barrier layer 110, a second channel layer 112, an insulating layer 116, a source electrode 118, a drain electrode 120, and a gate electrode 122. A 2DEG 108 occurs in the first channel layer 106. A 2DHG (2-dimensional hole gas) 114 occurs in the second channel layer 112.

The substrate 102 is a silicon substrate. In addition, the substrate 102 may be, for example, a sapphire substrate, a GaN substrate, an MgO substrate, a ZnO substrate, etc. The buffer layer 104 is formed on the substrate 102. When the substrate 102 is a silicon substrate, the buffer layer 104 is formed on a silicon (111) surface, for example. The buffer layer 104 buffers interactions between the first channel layer 106 and the substrate 102 that are due to differences in their properties such as lattice constant and coefficient of thermal expansion, and improves their joint strength. The buffer layer 104 is formed by stacking a plurality of AlN films and GaN films alternately on the substrate 102. For example, the buffer layer 104 may include on an AlN (aluminum nitride) film having a thickness of 100 nm, 3 to 20 layers of film stacks each including a GaN film having a thickness of 5 nm to 400 nm, and an AlN film having a thickness of 1 nm to 40 nm. For another example, the buffer layer 104 may be formed from undoped GaN. “Undoped” means a semiconductor film that is formed by intentionally not adding any impurity that imparts a conductivity type of either P or N.

The first channel layer 106 is formed on the buffer layer 104 from a GaN-based semiconductor. The barrier layer 110 is formed on the first channel layer 106. The barrier layer 110 is formed from a GaN-based semiconductor having a higher bandgap energy than the GaN-based semiconductor of the first channel layer 106. The second channel layer 112 is formed on the barrier layer 110. The second channel layer 112 is formed from a GaN-based semiconductor having a lower bandgap energy than the GaN-based semiconductor of the barrier layer 110. The first channel layer 106 and the second channel layer 112 may be formed from the same material, but they are not limited to this and may be formed from different materials.

For example, the first channel layer 106 and the second channel layer 112 are both formed from GaN, and the barrier layer 110 is formed from AlₓGa₁₋ₓN (0<x≦1). Here, it is more preferable that the first channel layer 106 and the barrier layer 110 be formed from an undoped GaN-based semiconductor and the second channel layer 112 be formed from a p-type GaN-based semiconductor. AlₓGa₁₋ₓN (0<x<1) is a mixed crystal of AlN and GaN. Depending on the composition ratio represented by x, the bandgap, spontaneous polarization, and piezo polarization of the barrier layer 110 changes.

When a silicon substrate is used as the substrate 102, and the buffer layer 104, the first channel layer 106, the barrier layer 110, and the second channel layer 112 are formed on a silicon (111) surface, the 2DEG 108 is formed in the first channel layer 106 proximate to the heterojunction interface with the barrier layer 110. This is because formation of a GaN-based semiconductor on a silicon (111) surface leads to formation of a GaN-based semiconductor having Ga polarity. The 2DEG 108 is formed by spontaneous polarization and piezo polarization at the heterojunction interface between the barrier layer 110 and the first channel layer 106. For example, when the barrier layer 110 is formed from Al_{0.2}Ga_{0.8}N and the thickness of the barrier layer 110 is 20 nm to 40 nm, the concentration of the 2DEG 108 is 1×10¹³ cm⁻³ or higher.

The 2DHG 114 is formed in the second channel layer 112 proximate the heterojunction interface with the barrier layer 110. This is because the side of the barrier layer 110 proximate the first channel layer 106 is polarized to the positive polarity. That is, since the second channel layer 112 is formed on the side of the barrier layer 110 that is polarized to the negative polarity, the 2DHG 114 occurs at the side of the second channel layer 112 proximate to the barrier layer 110. The concentration of the 2DHG 114 is higher when the second channel layer 112 is formed from a p-type GaN-based semiconductor than when the second channel layer 112 is not a p-type. The barrier layer 110 having a larger thickness will increase the carrier concentration of both the 2DEG 108 and the 2DHG 114, but will make it more likely for the barrier layer 110 and the second channel layer 112 to be cracked. Hence, it is preferable that the thickness of the barrier layer 110 be 40 nm to 60 nm.

Portions of the second channel layer 112 that are in regions separate from each other are removed. The source electrode 118 and the drain electrode 120 are formed on the barrier layer 110 in the regions from which the portions of the second channel layer 112 are removed. The source electrode 118 and the drain electrode 120 both have an ohmic contact with the 2DHG 114. The source electrode 118 and the drain electrode 120 both have Schottky contact with the 2DEG 108. For example, the source electrode 118 and the drain electrode 120 are both formed from Ni. The source electrode 118 and the drain electrode 120 both may further include Au above Ni. The source electrode 118 and the drain electrode 120 may further include either Pt or Mo. The source electrode 118 may have an ohmic contact with the 2DEG 108. For example, the source electrode 118 may be made of Ti.

A portion of the second channel layer 112 that is between the source electrode 118 and the drain electrode 120 is removed. The insulating layer 116 is formed between the source electrode 118 and the drain electrode 120. Between the source electrode 118 and the drain electrode 120, the insulating layer 116 is formed on the second channel layer 112. In the region from which the portion of the second channel layer 112 is removed, the insulating layer 116 is formed on the side surfaces of the second channel layer 112 and on the barrier layer 110. In regions that are not between the source electrode 118 and the drain electrode 120, the insulating layer 116 is also formed on the second channel layer 112. The insulating layer 116 is composed of for example, SiO₂.

In the region from which the portion of the second channel layer 112 is removed, the gate electrode 122 is formed on the insulating layer 116. The gate electrode 122 is formed from, for example, Ti. The gate electrode 122 may further include Au above Ti.

The potential of the 2DEG 108 is equipotential to the source electrode 118 or a potential close to the source electrode 118. When the gate electrode 122 is applied with a voltage that is equal to or higher than a threshold, the MOS type transistor 100 is in the Off state. That is, the hole concentration is lower in a region below the gate electrode 122 than the other regions that are between the source electrode 118 and the drain electrode 120. The threshold is, for example, the potential of the source electrode 118. The 2DHG 114 between the source electrode 118 and the gate electrode 122 may be electrically separated from the 2DHG 114 between the drain electrode 120 and the gate electrode 122 below the gate electrode 122.

When the gate electrode 122 is applied with a voltage that is lower than the threshold, holes are accumulated in a region below the gate electrode 122 at the side of the barrier layer 110 proximate to the gate electrode 122. The holes accumulated in the barrier layer 110 become connected with the 2DHG 114 to turn on the MOS type transistor 100. That is, the hole concentration in the region below the gate electrode 122 is controlled by the gate electrode 122 to make the MOS type transistor 100 function as a p-type transistor.

While the MOS type transistor 100 has been explained as above, the MOS transistor 100 is not limited to the embodiment described above. For example, the buffer layer 104, the first channel layer 106, the barrier layer 110, and the second channel layer 112 may be formed on the substrate 102 from a GaN-based semiconductor having N polarity. As a result, a 2DHG is formed in the first channel layer 106 proximate to the heterojunction interface with the barrier layer 110. A 2DEG is formed in the second channel layer 112 proximate to the heterojunction interface with the barrier layer 110.

For another example, in the region between the source electrode 118 and the drain electrode 120 from which a portion of the second channel layer 112 is removed and the insulating layer 116 and the gate electrode 122 are formed, the second channel layer 112 needs not be removed all across its thickness. That is, the second channel layer 112 may be thinner in a portion of the region between the source electrode 118 and the drain electrode 120 than in the other regions. In the region where the second channel layer 112 is thinner, the insulating layer 116 may be formed on the side surfaces and top surface of the second channel layer 112. This allows for adjusting the threshold of the MOS type transistor 100. For example, by providing a sufficient thickness to the portion of the second channel layer 112 where the second channel layer 112 is thinner, it is possible to provide a normally-on type MOS type transistor 100.

For another example, in the region between the source electrode 118 and the drain electrode 120 from which a portion of the second channel layer 112 is removed and the insulating layer 116 and the gate electrode 122 are formed, the barrier layer 110 may be removed partially in the thickness direction. That is, in a portion of the region between the source electrode 118 and the drain electrode 120, the barrier layer 110 may be thinner than in the other regions. In the region of the barrier layer 110 where it is thinner, the insulating layer 116 may be formed on the side surfaces and top surface of the barrier layer 110 and on the side surfaces of the second channel layer 112. This allows for adjusting the threshold of the MOS type transistor 100.

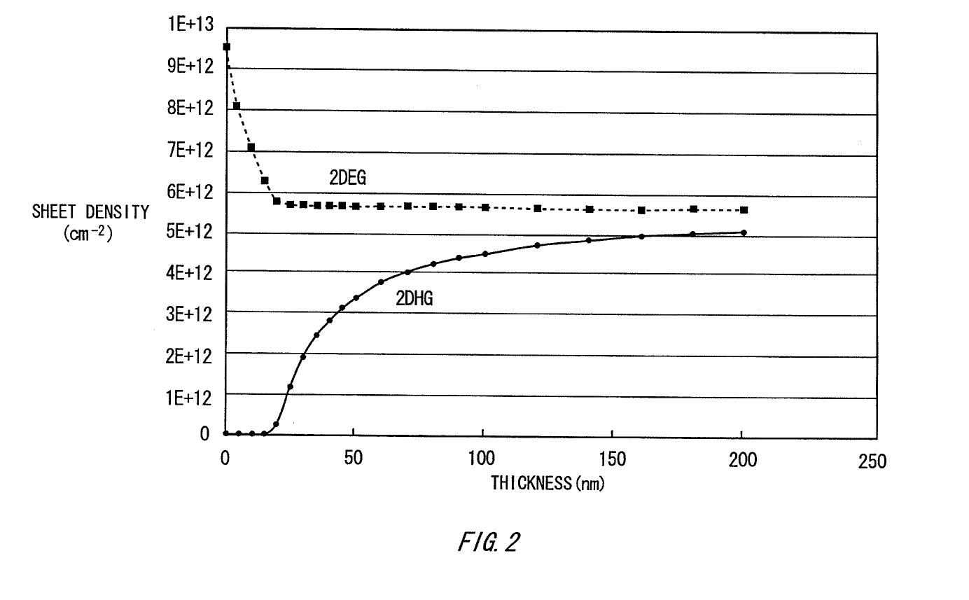

FIG. 2 is a graph showing the carrier concentration of the MOS type transistor 100 according to the first embodiment. The graph of FIG. 2 shows the carrier concentration of the MOS type transistor 100 in which the barrier layer 110 is formed from Al_{0.2}Ga_{0.8}N having a thickness of 28 nm. The second channel layer 112 is formed from undoped GaN. The horizontal axis represents the thickness (nm) of the second channel layer 112, and the vertical axis represents the sheet density (cm⁻²) of the 2DEG 108 and the 2DHG 114. The solid line represents the sheet density of the 2DHG 114, and the broken line represents the sheet density of the 2DEG 108.

When the thickness of the second channel layer 112 is 50 nm or larger, the sheet density of the 2DHG 114 is 3.2×10¹² cm⁻² or higher. Therefore, it is preferable that the thickness of the second channel layer 112 is 50 nm or larger. On the other hand, when the thickness of the second channel layer 112 is 200 nm, the sheet densities of both the 2DHG 114 and the 2DEG 108 are saturated. Therefore, the thickness of the second channel 112 may be 200 nm or smaller.

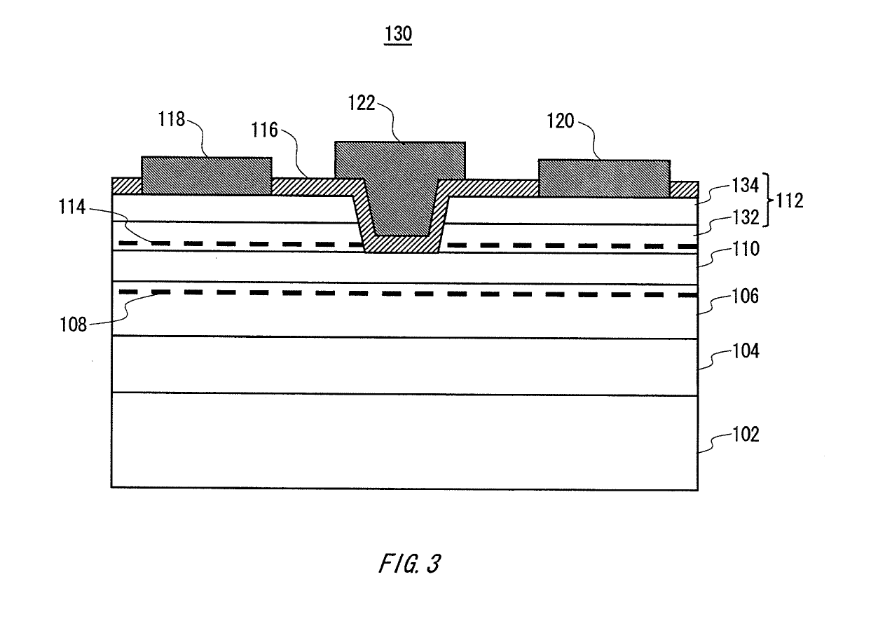

FIG. 3 is an exemplary cross-sectional diagram of a MOS type transistor 130 according to a second embodiment of the present invention. The MOS type transistor 130 includes a substrate 102, a buffer layer 104, a first channel layer 106, a barrier layer 110, a second channel layer 112, an insulating layer 116, a source electrode 118, a drain electrode 120, and a gate electrode 122. The second channel layer 112 includes an undoped semiconductor layer 132 and a p-type semiconductor layer 134. A 2DEG 108 is formed in the first channel layer 106. A 2DHG 114 is formed in the undoped semiconductor layer 132. Any elements of FIG. 3 that are given the same reference numerals as used in FIG. 1 have the same function and configuration as those of the elements explained with reference to FIG. 1.

The undoped semiconductor layer 132 is formed on the barrier layer 110 from an undoped GaN-based semiconductor. The p-type semiconductor layer 134 is formed on the undoped semiconductor layer 132 from a p-type GaN-based semiconductor. The source electrode 118 and the drain electrode 120 are formed on portions of the p-type semiconductor layer 134 that are separate from each other. The source electrode 118 and the drain electrode 120 have an ohmic contact with the p-type semiconductor layer 134.

Portions of the updoped semiconductor layer 132 and the p-type semiconductor layer 134 are removed from between the source electrode 118 and the drain electrode 120. Between the source electrode 118 and the drain electrode 120, the insulating layer 116 is formed on the p-type semiconductor layer 134. In the region where the portions of the undoped semiconductor layer 132 and p-type semiconductor layer 134 are removed, the insulating layer 116 is formed on the side surfaces of the undoped semiconductor layer 132 and p-type semiconductor layer 134 and on the barrier layer 110. The insulating layer 116 is also formed on other regions of the p-type semiconductor layer 134 than the region between the source electrode 118 and the drain electrode 120. In the region from which the portions of the undoped semiconductor layer 132 and the p-type semiconductor layer 134 are removed, the gate electrode 122 is formed on the insulating layer 116.

The 2DHG 114 occurs in the undoped semiconductor layer 132 proximate to the heterojunction interface with the barrier layer 110. When the gate electrode 122 is applied with a voltage that is equal to or lower than a threshold, holes are accumulated at the side of the barrier layer 110 proximate to the gate electrode 122. Hence, the MOS type transistor 130 functions as a p-type transistor. The threshold is, for example, the potential of the source electrode 118.

As another configuration, in the region between the source electrode 118 and the drain electrode 120 from which the portions of the undoped semiconductor layer 132 and p-type semiconductor layer 134 are removed and the insulating layer 116 and the gate electrode 122 are formed, the undoped semiconductor layer 132 needs not be removed all across its thickness. That is, in a portion of the region between the source electrode 118 and the drain electrode 120, a portion of the p-type semiconductor layer 134 is removed. In the region from which the portion of the p-type semiconductor layer 134 is removed, the undoped semiconductor layer 132 may be thinner than in the other regions. In the region where the undoped semiconductor layer 132 is thinner, the insulating layer 116 may be formed on the side surfaces of the p-type semiconductor layer 134 and on the side surfaces and top surface of the undoped semiconductor layer 132. This allows for adjusting the threshold of the MOS type transistor 130.

For another example, in the region between the source electrode 118 and the drain electrode 120 from which the portions of the undoped semiconductor layer 132 and p-type semiconductor layer 134 are removed and the insulating layer 116 and the gate electrode 122 are formed, the barrier layer 110 may be removed partially in the thickness direction. That is, in a portion of the region between the source electrode 118 and the drain electrode 120, the barrier layer 110 may be thinner than in the other regions. In the region where the barrier layer 110 is thinner, the insulating layer 116 may be formed on the side surfaces and top surface of the barrier layer 110 and the side surfaces of the undoped semiconductor layer 132 and p-type semiconductor layer 134. This allows for adjusting the threshold of the MOS type transistor 130.

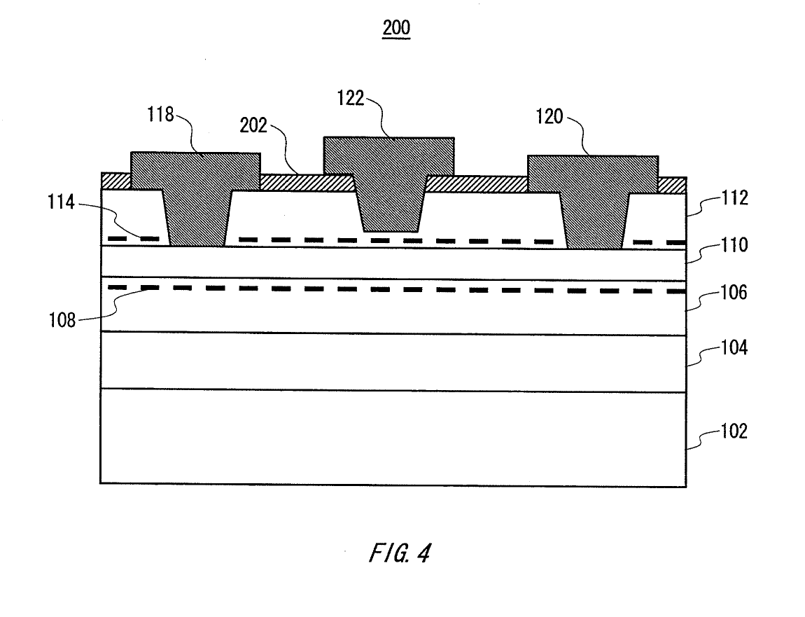

FIG. 4 is an exemplary cross-sectional diagram of a Schottky gate type transistor 200 according to a third embodiment of the present invention. The Schottky gate type transistor 200 includes a substrate 102, a buffer layer 104, a first channel layer 106, a barrier layer 110, a second channel layer 112, a protection film 202, a source electrode 118, a drain electrode 120, and a gate electrode 122. A 2DEG 108 is formed in the first channel layer 106. A 2DHG 114 is formed in the second channel layer 112. Any elements of FIG. 4 that are given the same reference numerals as used in FIG. 1 have the same function and configuration as those of the elements explained with reference to FIG. 1.

Portions of the second channel layer 112 that are in regions separate from each other are removed. In the regions from which the portions of the second channel layer 112 are removed, the source electrode 118 and the drain electrode 120 are formed on the barrier layer 110. The source electrode 118 and the drain electrode 120 both have Schottky contact with the 2DEG 108. The source electrode 118 and the drain electrode 120 both have Schottky contact with the 2DEG 108. The source electrode 118 may have an ohmic contact with the 2DEG 108. Between the source electrode 118 and the drain electrode 120, the protection film 202 is formed on the second channel layer 112. The protection film 202 is also formed on other regions of the second channel layer 112 than the region between the source electrode 118 and the drain electrode 120.

The protection film 202 is removed from a portion of the region between the source electrode 118 and the drain electrode 120. In the region between the source electrode 118 and the drain electrode 120 from which the protection film 202 is removed, the second channel layer 112 is removed partially in the thickness direction to make the second channel layer 112 thinner than in the other regions. In the region where the second channel layer 112 is thinner than the second channel layer 112 in the other regions, the concentration of the 2DHG 114 is lower.

In the region from which the portion of the second channel layer 112 and the protection film 202 are removed, the gate electrode 122 is formed on the second channel layer 112. The gate electrode 122 has Schottky contact with the second channel layer 112. For example, the gate electrode 122 is formed from Ni. The gate electrode 122 may further include Au above Ni.

When the gate electrode 122 is applied with a voltage that is lower than a threshold, holes are accumulated in the second channel layer 112 in a region below the gate electrode 122. The threshold is, for example, the potential of the source electrode 118. The holes accumulated in the second channel layer 112 are connected with the 2DHG 114 to turn on the Schottky gate type transistor 200. That is, the Schottky gate type transistor 200 functions as a p-type transistor.

For another example, in the region between the source electrode 118 and the drain electrode 120 from which the second channel layer 112 is to be removed, the gate electrode 122 may be formed on the barrier layer 110 with the second channel layer 112 removed all across. Further, in the region from which the second channel layer 112 is removed, the barrier layer 110 may be removed partially in the thickness direction. That is, in a portion of the region between the source electrode 118 and the drain electrode 120, the barrier layer 110 may be thinner than in the other regions. In the region where the barrier layer 110 is thinner, the gate electrode 122 may be formed on the side surfaces and top surface of the barrier layer 110 and on the side surfaces of the second channel layer 112. This allows for adjusting the threshold of the Schottky gate type transistor 200.

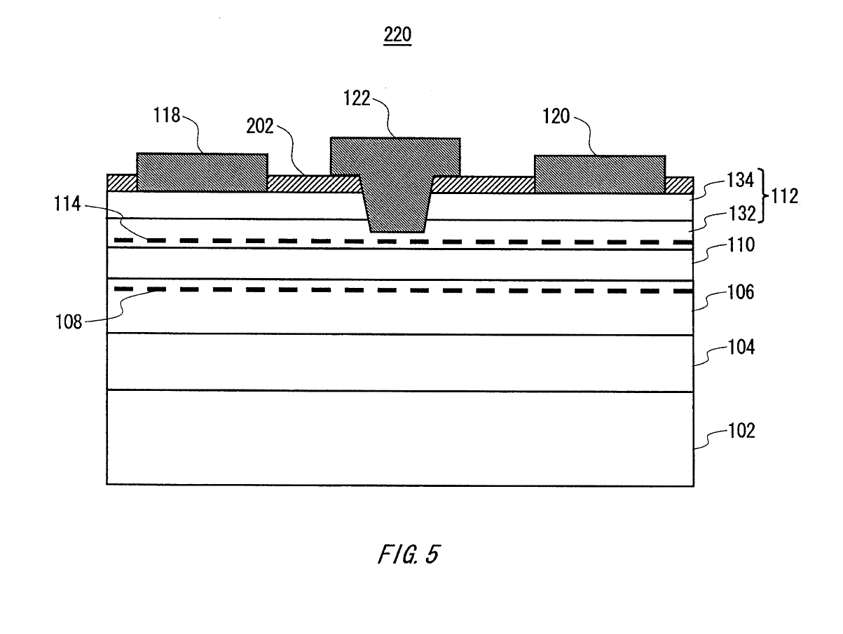

FIG. 5 is an exemplary cross-sectional diagram of a Schottky gate type transistor 220 according to a fourth embodiment of the present invention. The Schottky gate type transistor 220 includes a substrate 102, a buffer layer 104, a first channel layer 106, a barrier layer 110, a second channel layer 112, a protection film 202, a source electrode 118, a drain electrode 120, and a gate electrode 122. The second channel layer 112 includes an undoped semiconductor layer 132 and a p-type semiconductor layer 134. A 2DEG 108 is formed in the first channel layer 106. A 2DHG 114 is formed in the undoped semiconductor layer 132. Any elements of FIG. 5 that are given the same reference numerals as used in FIG. 3 and FIG. 4 have the same function and configuration as those of the elements explained with reference to FIG. 3 and FIG. 4.

The undoped semiconductor layer 132 is formed on the barrier layer 110 from an undoped GaN-based semiconductor. The p-type semiconductor layer 134 is formed on the undoped semiconductor layer 132 from a p-type GaN-based semiconductor. The source electrode 118 and the drain electrode 120 are formed on portions of the p-type semiconductor layer 134 that are separate from each other. The source electrode 118 and the drain electrode 120 have an ohmic contact with the p-type semiconductor layer 134. Between the source electrode 118 and the drain electrode 120, the protection film 202 is formed on the second channel layer 112. The protection film 202 is also formed on other regions of the second channel layer 112 than the region between the source electrode 118 and the drain electrode 120.

The protection film 202 and the p-type semiconductor layer 134 are removed from a portion of the region between the source electrode 118 and the drain electrode 120. In the region between the source electrode 118 and the drain electrode 120 from which the protection film 202 and the p-type semiconductor layer 134 are removed, the undoped semiconductor layer 132 is removed partially in the thickness direction to make the undoped semiconductor layer 132 thinner than in the other regions. Since the undoped semiconductor layer 132 is thinner than the undoped semiconductor layer 132 in the other regions, the concentration of the 2DHG 114 is lower in this region.

In the region from which a portion of the undoped semiconductor layer 132, the p-type semiconductor layer 134, and the protection film 202 are removed, the gate electrode 122 is formed on the undoped semiconductor layer 132. The gate electrode 122 has Schottky contact with the undoped semiconductor layer 132.

When the gate electrode 122 is applied with a voltage that is lower than a threshold, holes are accumulated in the undoped semiconductor layer 132 in a region below the gate electrode 122. The threshold is, for example, the potential of the source electrode 118. The holes accumulated in the undoped semiconductor layer 132 are connected with the 2DHG 114 to turn on the Schottky gate type transistor 200. That is, the Schottky gate type transistor 200 functions as a p-type transistor.

For another example, in the region between the source electrode 118 and the drain electrode 120 from which the p-type semiconductor layer 134 is removed, the gate electrode 122 may be formed on the barrier layer 110 with the undoped semiconductor layer 132 removed all across. Further, in the region from which the undoped semiconductor layer 132 is removed, the barrier layer 110 may be removed partially in the thickness direction. That is, in a portion of the region between the source electrode 118 and the drain electrode 120, the barrier layer 110 may be thinner than in the other regions. Then, in the region where the barrier layer 110 is thinner, the gate electrode 122 may be formed on the side surfaces and top surface of the barrier layer 110, and on the side surfaces of the undoped semiconductor layer 132 and p-type semiconductor layer 134. This allows for adjusting the threshold of the Schottky gate type transistor 220.

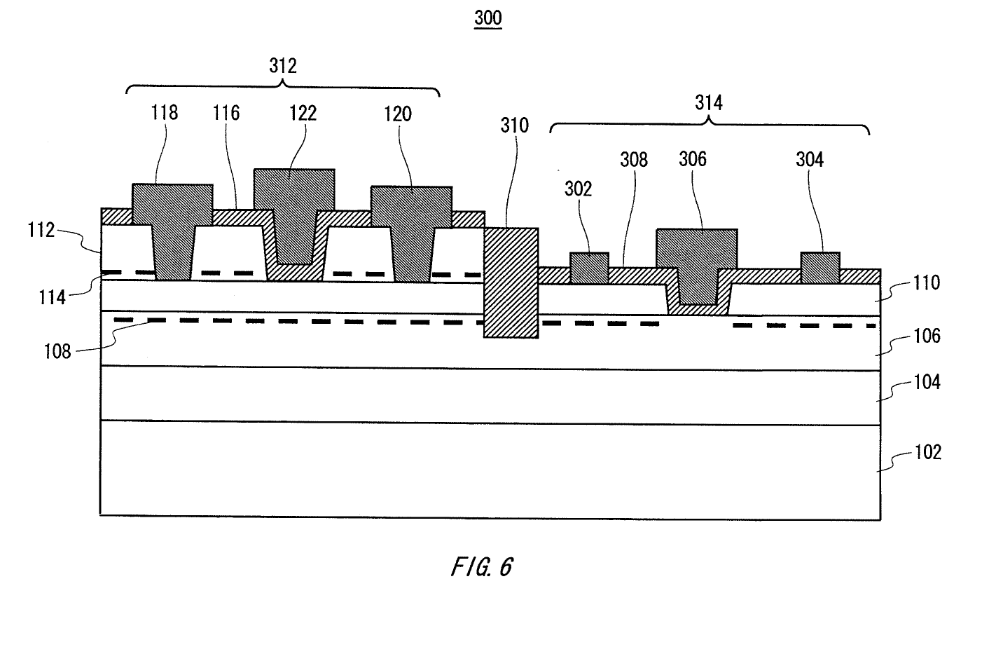

FIG. 6 is an exemplary cross-sectional diagram of a complementary transistor 300 according to a fifth embodiment of the present invention. The complementary transistor 300 includes a p-type transistor 312, an n-type transistor 314, and an isolationg region 310. The p-type transistor 312 is the MOS type transistor 100 according to the first embodiment. Any elements of FIG. 6 that are given the same reference numerals as used in FIG. 1 have the same function and configuration as those of the elements explained with reference to FIG. 1.

The isolating region 310 is formed between the p-type transistor 312 and the n-type transistor 314 to separate the p-type transistor 312 from the n-type transistor 314. The isolating region 310 extends through the second channel layer 112 and the barrier layer 110. The isolating region 310 is also formed in the first channel layer 106 partially in the thickness direction to go across the 2DEG 108. The isolating region 310 is formed by implanting Fe ions into the second channel layer 112, the barrier layer 110, and the first channel layer 106.

The isolating region 310 is not limited to the above example, but may be formed by implanting F ions into the second channel layer 112, the barrier layer 110, and the first channel layer 106. The isolating region 310 may be formed by oxidizing the second channel layer 112, the barrier layer 110, and the first channel layer 106. The isolating region 310 may be a recess formed by removing the second channel layer 112, the barrier layer 110, and the first channel layer 106. Further, the isolating region 310 may be formed to extend through the first channel layer 106.

The n-type transistor 314 includes the substrate 102, the buffer layer 104, the first channel layer 106, the barrier layer 110, an insulating film 308, a source electrode 302, a drain electrode 304, and a gate electrode 306. The source electrode 302 and the drain electrode 304, which are separate from each other, are formed on portions of the barrier layer 110. The source electrode 302 and the drain electrode 304 have an ohmic contact with the first channel layer 106.

In the region between the source electrode 302 and the drain electrode 304, the barrier layer 110 is partially removed to form a recess in the barrier layer 110. In regions where the source electrode 302 and the drain electrode 304 are not formed, the insulating film 308 is formed on the barrier layer 110. In the region from which the barrier layer 110 is removed, the insulating film 308 is formed to cover the internal surfaces of the recess in the barrier layer 110 and the first channel layer 106. In the region from which the barrier layer 110 is removed, the gate electrode 306 is formed on the insulating film 308. In the region from which the barrier layer 110 is removed, the 2DEG 108 does not occur in the first channel layer 106.

The n-type transistor 314 is formed by forming the buffer layer 104, the first channel layer 106, the barrier layer 110, and the second channel layer 112 on the substrate 102, and then removing the second channel layer 112 before forming the p-type transistor 312 or after forming the p-type transistor 312. The second channel layer 112 is removed by, for example, etching. This allows for the p-type transistor 312 and the n-type transistor 314 to be formed on the same substrate serially.

When the n-type transistor 314 is applied with a voltage that is equal to or higher than a threshold, electrons are accumulated in the first channel layer 106 below the gate electrode 306. In this way, the carrier concentration in the region below the gate electrode 306 is controlled by the gate electrode 306 to turn on the n-type transistor 314.

In the recess in the barrier layer 110, the first channel layer 106 may be removed in the thickness direction, so that the first channel layer 106 may be thinner than in the other regions. In this way, the threshold of the n-type transistor 314 may be adjusted.

The complementary transistor 300 functions as a complementary transistor as it includes the p-type transistor 312 and the n-type transistor 314. Therefore, it is possible to form a transistor with a smaller power consumption and a smaller size than when forming both of an enhancement-type transistor and a depletion-type transistor.

Though an example in which the p-type transistor 312 is the MOS type transistor 100 according to the first embodiment has been explained, the present invention is not limited to this. For example, the p-type transistor 312 may be the p-type transistor according to any of the second to fourth embodiments. Further, the n-type transistor 314 is not limited to a MOSFET. For example, the n-type transistor 314 may be an FIEMT.

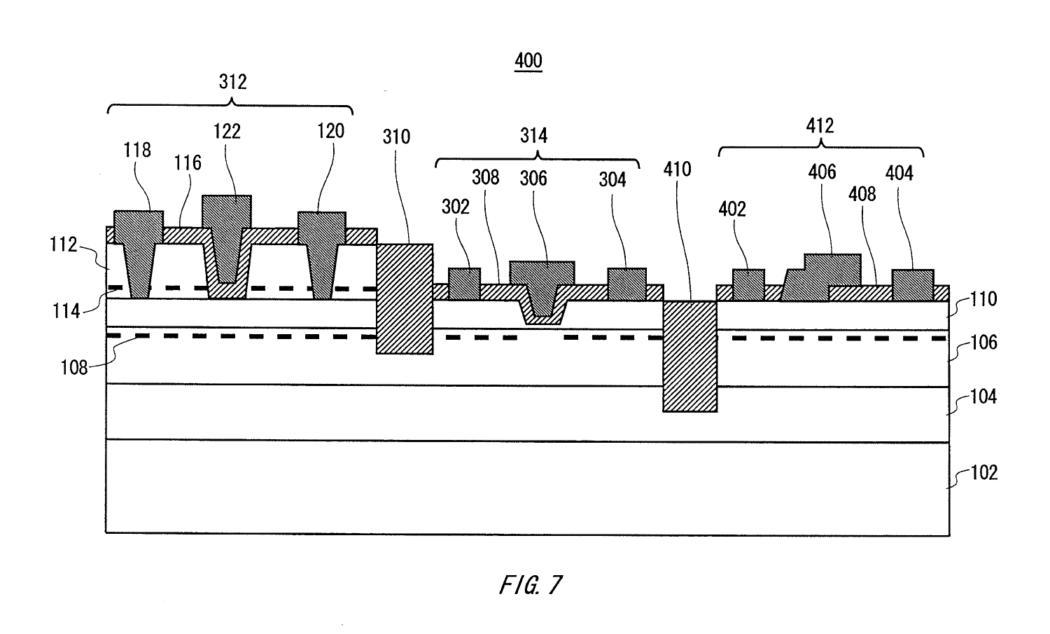

FIG. 7 is an exemplary cross-sectional diagram of a semiconductor device 400 according to a sixth embodiment of the present invention. The semiconductor device 400 includes a p-type transistor 312, an n-type transistor 314, a high-voltage element 412, an isolationg region 310, and an isolationg region 410. The p-type transistor 312, the isolating region 310, and the n-type transistor 314 have the same configuration and function as those of the corresponding elements of the complementary transistor 300 according to the fifth embodiment. Any elements of FIG. 7 that are given the same reference numerals as used in FIG. 6 have the same function and configuration as those of the elements explained with reference to FIG. 6.

The high-voltage between a source electrode 402 and a drain electrode 404 when the high-voltage element 412 is in the Off state is higher than any of a high-voltage between the source electrode 118 and the drain electrode 120 when the p-type transistor 312 is in the Off state and a high-voltage between the source electrode 302 and the drain electrode 304 when the n-type transistor 314 is in the Off state.

The isolating region 410 is formed between the p-type transistor 312 and n-type transistor 314 and the high-voltage element 412 to separate the p-type transistor 312 and n-type transistor 314 from the high-voltage element 412. The isolating region 410 extends through the barrier layer 110 and the first channel layer 106. The isolating region 410 is formed in the buffer layer 104 partially in the thickness direction. The isolating region 410 is formed by implanting Fe ions into the barrier layer 110, the first channel layer 106, and the buffer layer 104.

The isolating region 410 is not limited to the above example, but may be formed by implanting F ions into the barrier layer 110, the first channel layer 106, and the buffer layer 104. The isolating region 410 may be formed by oxidizing the barrier layer 110, the first channel layer 106, and the buffer layer 104. The isolating region 410 may be a recess formed by removing the barrier layer 110, the first channel layer 106, and the buffer layer 104. Further, the isolating region 410 may be formed to extend through the buffer layer 104.

The high-voltage element 412 is an HEMT in which the carrier is a 2DEG 108. The high-voltage element 412 includes the substrate 102, the buffer layer 104, the first channel layer 106, the barrier layer 110, the source electrode 402, the drain electrode 404, a gate electrode 406, and an insulating film 408. The source electrode 402 and the drain electrode 404 are formed on portions of the barrier layer 110 that are separated from each other. The source electrode 402 and the drain electrode 404 have an ohmic contact with the first channel layer 106. The gate electrode 406 is formed between the source electrode 402 and the drain electrode 404. The gate electrode 406 has Schottky contact with the first channel layer 106. In regions where the source electrode 402, the drain electrode 404, and the gate electrode 406 are not formed, the insulating film 408 is formed on the barrier layer 110. The gate electrode 406 has a field plate configuration in which it is also formed on the insulating film 408 on the side closer to the drain electrode 404.

Though a case has been explained in which the high-voltage element 412 is an HEMT, the present invention is not limited to this. For example, the high-voltage element 412 may be any of a MOSFET, a PN diode, and a Schottky diode.

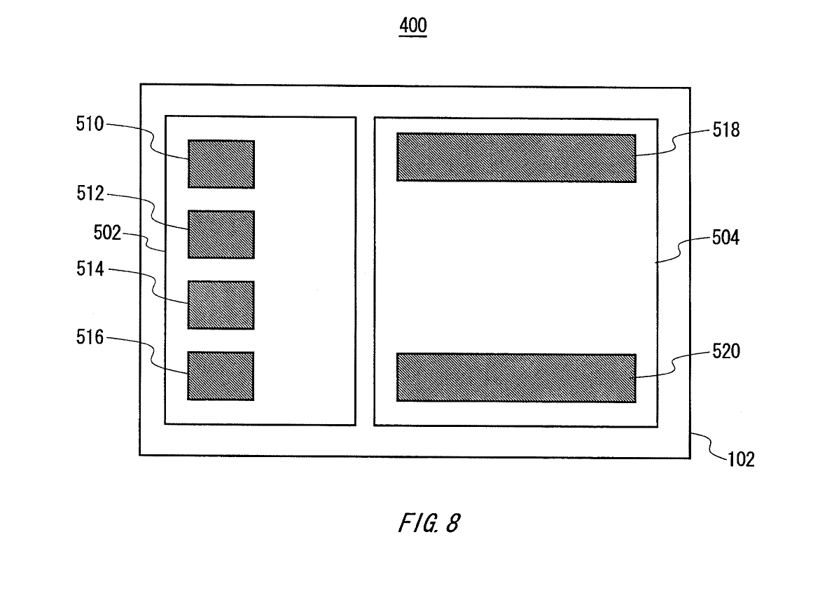

FIG. 8 is an exemplary plan diagram of the semiconductor device 400 according to the sixth embodiment. The semiconductor device 400 includes a circuit region 502 and a power region 504, which are formed on the substrate 102. The circuit region 502 includes a Vss electrode pad 510, a Vdd electrode pad 512, a Vin electrode pad 514, and a status electrode pad 516. A drive circuit including the p-type transistor 312 and the n-type transistor 314 is formed in the circuit region 502, and the Vss electrode pad 510, the Vdd electrode pad 512, the Vin electrode pad 514, and the status electrode pad 516 are electrically connected to the drive circuit. The Vss electrode pad 510 is supplied with a source voltage of the drive circuit. The Vdd electrode pad 512 is supplied with a drain voltage of the drive circuit. The Vin electrode pad 514 is supplied with a power supply regulator voltage of the drive circuit. The status electrode pad 516 is connected with a status lead of the drive circuit.

The power region 504 includes a source electrode pad 518 and a drain electrode pad 520. The high-voltage element 412 is formed in the power region 504. The source electrode 402 of the high-voltage element 412 is electrically connected to the source electrode pad 518. The drain electrode 404 of the high-voltage element 412 is electrically connected to the drain electrode pad 520. The gate electrode 406 of the high-voltage element 412 is electrically connected to the drive circuit formed in the circuit region 502.

Since the high-voltage element 412 and the drive circuit for driving the high-voltage element 412 are formed on the same substrate, the wiring length of the semiconductor device 400 can be reduced, which leads to reduction of wiring noise. Further, since the drive circuit for driving the high-voltage element 412 is constituted by a complementary transistor using GaN-based semiconductors, the device can operate up to a high temperature, reduce power consumption, and have a small size.

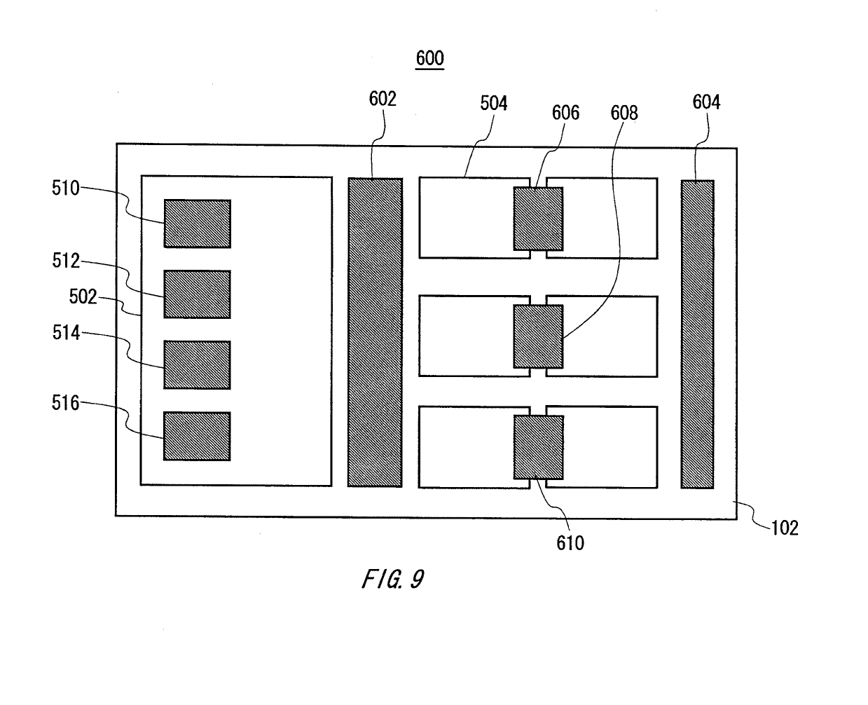

FIG. 9 is a plan diagram of an inverter 600 according to a seventh embodiment of the present invention. The inverter 600 includes a circuit region 502, a plurality of power regions 504, a ground electrode pad 602, a Vcc electrode pad 604, a U-phase electrode pad 606, a V-phase electrode pad 608, and a W-phase electrode pad 610, which are formed on a substrate 102. The circuit region 502 includes a Vss electrode pad 510, a Vdd electrode pad 512, a Vin electrode pad 514, and a status electrode pad 516. A drive circuit including a p-type transistor 312 and an n-type transistor 314 is formed in the circuit region 502, and the Vss electrode pad 510, the Vdd electrode pad 512, the Vin electrode pad 514, and the status electrode pad 516 are electrically connected to the drive circuit. Any elements that are given the same reference numerals as used in FIG. 6 have the same function and configuration as those of the elements explained with reference to FIG. 6.

A high-voltage element 412 is formed in the power regions 504. The power regions 504 are connected to the ground electrode pad 602 and the Vcc electrode pad 604. The ground electrode pad 602 is grounded. The Vcc electrode pad 604 is supplied with a positive power supply voltage. The inverter 600 includes six power regions 504. The U-phase electrode pad 606, the V-phase electrode pad 608, and the W-phase electrode pad 610 are each connected to two power regions 504. The U-phase electrode pad 606, the V-phase electrode pad 608, and the W-phase electrode pad 610 are supplied with a U-phase, a V-phase, and a W-phase of a 3-phase alternating current, respectively.

The high-voltage element 412 formed in the power regions 504 is driven by the drive circuit formed in the circuit region 502. Since the high-voltage element 412 and the drive circuit for driving the high-voltage element 412 are formed on the same substrate, the wiring length of the inverter 600 can be reduced, which leads to reduction of wiring noise. Further, since the drive circuit for driving the high-voltage element 412 is constituted by a complementary transistor using GaN-based semiconductors, the inverter can operate up to a high temperature, reduce power consumption, and have a small size.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A GaN-based semiconductor device, comprising:
a first channel layer which is formed from a GaN-based semiconductor, and in which a carrier gas of a first conductivity type occurs;
a barrier layer formed on the first channel layer from a GaN-based semiconductor having a higher bandgap than the GaN-based semiconductor of the first channel layer;
a second channel layer which is formed on the barrier layer from a GaN-based semiconductor having a lower bandgap than the GaN-based semiconductor of the barrier layer, and in which a carrier gas of a second conductivity type occurs;
a first source electrode having an ohmic contact with the second channel layer;
a first drain electrode having an ohmic contact with the second channel layer;
a first gate electrode formed between the first source electrode and the first drain electrode,
wherein a carrier concentration of the carrier gas of the second conductivity type is lower in a region below the first gate electrode than in other regions that are between the first source electrode and the first drain electrode, the carrier concentration being controlled by the first gate electrode.

2. The GaN-based semiconductor device according to claim 1, wherein the second channel layer is thinner in the region below the first gate electrode than in the other regions that are between the first source electrode and the first drain electrode.

3. The GaN-based semiconductor device according to claim 1, further comprising an insulating layer formed between the first gate electrode and the barrier layer.

4. The GaN-based semiconductor device according to claim 3, wherein the second channel layer is removed from the region below the first gate electrode.

5. The GaN-based semiconductor device according to claim 4, wherein the barrier layer is thinner in the region below the first gate electrode than in the other regions that are between the first source electrode and the first drain electrode.

6. The GaN-based semiconductor device according to claim 1, wherein a current between the first channel layer and the first drain electrode is suppressed.

7. The GaN-based semiconductor device according to claim 1, wherein Schottky contact is provided between the first drain electrode and the first channel layer.

8. The GaN-based semiconductor device according to claim 1, wherein the source electrode has an ohmic contact with the first channel layer.

9. The GaN-based semiconductor device according to claim 1, wherein
the first channel layer is formed from GaN,
the barrier layer is formed from AlGaN, and
the second channel layer is formed from GaN.

10. The GaN-based semiconductor device according to claim 1,
wherein the second channel layer includes:
a lower second channel layer formed on the barrier layer; and
an upper second channel layer formed on the lower second channel layer.

11. The GaN-based semiconductor device according to claim 10, wherein
the lower second channel layer is formed from undoped GaN, and
the upper second channel layer is formed from p-type GaN.

12. The GaN based semiconductor layer according to claim 10, wherein the upper second channel layer is removed from the region below the first gate electrode.

13. The GaN-based semiconductor device according to claim 1, wherein
the carrier gas of the first conductivity type is a 2-dimensional electron gas, and
the carrier gas of the second conductivity type is a 2-dimensional hole gas.

14. The GaN-based semiconductor device according to claim 1, further comprising:
a second source electrode having an ohmic contact with the first channel layer;
a second drain electrode having an ohmic contact with the first channel layer; and
a second gate electrode which is formed between the second source electrode and the second drain electrode, and which controls a carrier concentration of the first channel layer.

15. The GaN-based semiconductor device according to claim 14, further comprising an isolationg region which is formed between the first source electrode, first drain electrode, and first gate electrode and the second source electrode, second drain electrode, and second gate electrode, and which separates the carrier gas of the first conductivity type.

16. The GaN-based semiconductor device according to claim 14, further comprising a semiconductor device using the carrier gas of the first conductivity type as a carrier,
wherein a high-voltage of the semiconductor device when it is in an Off state is higher than any of a high-voltage of a first transistor when it is in an Off state, and a high-voltage of a second transistor when it is in an Off state, the first transistor including the first source electrode, the first drain electrode, and the first gate electrode, and the second transistor including the second source electrode, the second drain electrode, and the second gate electrode.

17. The GaN-based semiconductor device according to claim 16, wherein the semiconductor device is controlled by the first transistor and the second transistor.
